(19) United States
(12) Patent Application Publication
(10) Pub. No.: US 2019/0382891 A1
(43) Pub. Date: Dec. 19, 2019

(54) METHOD AND SOLUTION FOR RESOLVING CGT MURA ISSUE

(71) Applicant: Applied Materials, Inc., Santa Clara, CA (US)

(72) Inventors: Shouqian SHAO, Fremont, CA (US); Jianhua ZHOU, Campbell, CA (US); Fu-Ting CHANG, Tainan City (TW); Yi CUI, San Jose, CA (US); Jun LI, Sunnyvale, CA (US)

(21) Appl. No.: 16/011,381

(22) Filed: Jun. 18, 2018

(51) Int. Cl. C23C 16/458; C23C 16/455; H01J 37/32

(52) U.S. Cl. CPC C23C 16/4583; C23C 16/45565; C23C 16/50; H01J 37/32183; H01J 37/32724

(57) ABSTRACT

Embodiments described herein provide an apparatus for providing an inductance at positions that correspond to positions of substrate support pins. The apparatus includes one or more substrate support pins. Each substrate support pin includes a head portion, a first portion, and a second portion. The second portion is an inductor that provides inductance at positions of substrate support pins. The inductance provided by the second portion of the substrate support pin changes the impedance to match the impedance at areas of the substrate support without the substrate support pins. With matched impedance, the plasma density over the areas of the substrate support with the support pins and without the support pins is uniform, leading to improved film thickness uniformity. The uniform film thickness thus reduces or eliminates clouding or the “mura effect”.

### BACKGROUND

### Field

Embodiments disclosed herein generally relate to apparatus for depositing films on a substrate and more specifically, to apparatus for facilitating uniform thickness of the films deposited on a substrate.

### Description of the Related Art

Electronic devices, such as thin film transistors (TFT's), photovoltaic (PV) devices or solar cells and other electronic devices have been fabricated on thin, flexible media for many years. The substrates may be made of glass, polymers, or other material suitable for electronic device formation. The substrates are typically processed in a tool that has multiple chambers, such as a cluster tool, and the substrates are transferred into and out of the various chambers that perform different processing steps in order to form the electronic devices thereon.

To facilitate transfer of the substrates into and out of the chambers, substrate support pins that extend through an upper surface of a substrate support based on movement of the substrate support, are utilized. For example, lowering of the substrate support actuates the substrate support pins such that the support pins contact the substrate so that the substrate may be spaced apart from the substrate support. This spacing allows a transfer mechanism, such as a robot blade or end effector, to move between the substrate and the upper surface of the substrate support and lift the substrate off the substrate support without causing damage to the substrate support or the substrate. When the substrate support is raised, the substrate support pins retract into the surface of the substrate support thereby placing the substrate into contact with the surface, and the substrate support pins rest under the substrate during processing thereof.

However, the areas of the substrate where the substrate support pins are located suffer from sub-optimal deposition as compared to other areas of the substrate. For example, the areas of the substrate corresponding to the locations of the substrate support pins have a film thickness that is less than a film thickness as compared to other areas of the substrate. This occurs for various reasons, one of which may be a difference in temperature of the substrate where the substrate support pins are located. The sub-optimal deposition of the substrate at locations corresponding to the locations of the substrate support pins may create problems in the final display product, one major problem being a “mura effect” or “clouding” of portions of the final display product, which typically corresponds to the locations of the substrate support pins.

What is needed are apparatus to prevent or minimize the non-uniform deposition of areas of a substrate to the locations of the substrate support pins.

### SUMMARY

Embodiments described herein provide an apparatus for providing an inductance at positions that correspond to positions of substrate support pins. In one embodiment, a substrate support pin includes a head portion having a first lateral dimension, a first portion coupled to the head portion, the first portion having a second lateral dimension substantially less than the first dimension, and a second portion coupled to the first portion, the second portion is a metal coil.

In another embodiment, a support pedestal for a vacuum chamber includes a body having a plurality of openings formed between two major sides of the body, and a substrate support pin disposed in each of the plurality of openings. Each of the substrate support pins includes a head portion having a first lateral dimension, a first portion coupled to the head portion, the first portion having a second lateral dimension substantially less than the first dimension, and a second portion coupled to the first portion, the second portion is a metal coil.

In another embodiment, an apparatus includes a chamber body defining a processing volume, and a substrate support disposed in the processing volume. The substrate support includes a body having a plurality of openings formed between two major sides of the body, and a substrate support pin disposed in each of the plurality of openings. Each of the substrate support pins includes a head portion having a first lateral dimension, a first portion coupled to the head portion, the first portion having a second lateral dimension substantially less than the first dimension, and a second portion coupled to the first portion, the second portion is a metal coil.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of one embodiment of a processing system having a substrate support according to one embodiment.

FIG. 2 is a side view of a support pin according to one embodiment.

FIGS. 3A-3B are exploded views of the support pin of FIG. 2 according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide an apparatus for providing an inductance at positions that correspond to positions of substrate support pins. The apparatus includes one or more substrate support pins. Each substrate support pin includes a head portion, a first portion, and a second portion. The second portion is an inductor that provides inductance at positions of substrate support pins. The inductance provided by the second portion of the substrate support pin changes the impedance to match the impedance at areas of the substrate support without the substrate support pins. With matched impedance, the plasma density over the areas of the substrate support with the support pins and without the support pins is uniform, leading to improved film thickness uniformity. The uniform film thickness thus reduces or eliminates clouding or the “mura effect”.

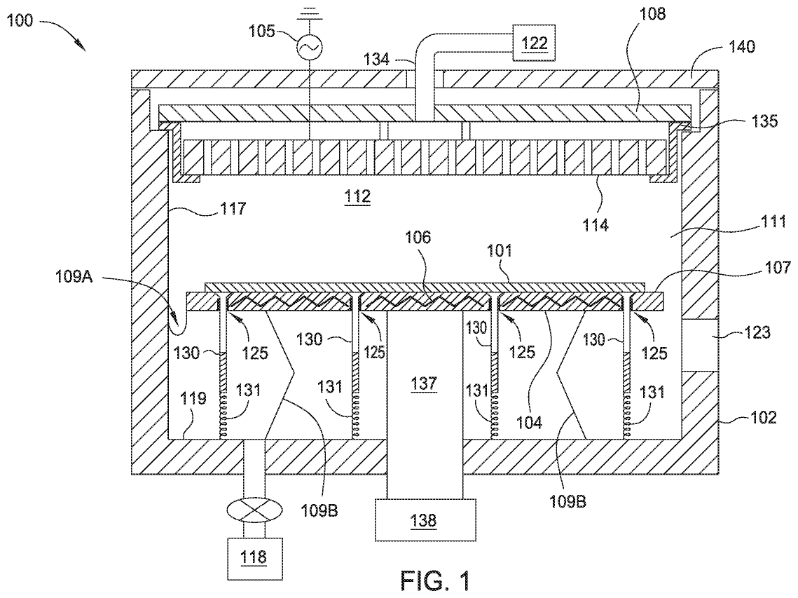

FIG. 1 is a schematic cross-sectional view of one embodiment of a processing system 100 having a substrate support according to one embodiment. In one embodiment, the processing system 100 is configured to process flexible media, such as a large area substrate 101, using plasma to form structures and devices on the large area substrate 101. The structures formed by the processing system 100 may be adapted for use in the fabrication of liquid crystal displays (LCD's), flat panel displays, organic light emitting diodes (OLED's), or photovoltaic cells for solar cell arrays. The substrate 101 may be thin sheet of metal, plastic, organic material, silicon, glass, quartz, or polymer, among others suitable materials. The substrate 101 may have a surface area greater than about 1 square meter, such as greater than about 2 square meters. The structures may include one or more junctions used to form part of a thin film photovoltaic device or solar cell. In another embodiment, the structures may be a part of a thin film transistor (TFT) used to form a LCD or TFT type device. It is also contemplated that the processing system 100 may be adapted to process substrates of other sizes and types, and may be used to fabricate other structures.

As shown in FIG. 1, the processing system 100 generally comprises a chamber body 102 including a sidewall 117, a bottom 119, and a backing plate 108 defining a processing volume 111. A lid 140 may be disposed over the backing plate 108. An opening 123 is formed in the sidewall 117 that is used to transfer substrates between the substrate support 104 and a transfer chamber or load lock chamber (both not shown).

A pedestal or substrate support 104 is disposed in the processing volume 111 opposing a showerhead assembly 114. The substrate support 104 is adapted to support the substrate 101 on an upper or support surface 107 during processing. The substrate support 104 is also coupled to an actuator 138 via a hollow shaft 137. The actuator is configured to move the substrate support 104 at least vertically to facilitate transfer of the substrate 101 and/or adjust a distance between the substrate 101 and the showerhead assembly 114. One or more support pins 130 extend through the substrate support 104. Each of the support pins 130 is movably disposed within a corresponding opening 125 formed in the substrate support 104. Each of the support pins 130 is connected to the bottom 119 by a connector 131. In one embodiment, the connector 131 is a coiled wire made of a conductive metal, such as aluminum. In another embodiment, the connector 131 is a strap or straps made of a conductive metal, such as aluminum.

In the embodiment shown in FIG. 1, the substrate support 104 is shown in a processing position near the showerhead assembly 114. In the processing position, the support pins 130 are adapted to be flush with or slightly below the support surface 107 of the substrate support 104 to allow the substrate 101 to lie flat on the substrate support 104. A processing gas source 122 is coupled by a conduit 134 to deliver process gases through the showerhead assembly 114 and into the processing volume 111. The processing system 100 also includes an exhaust system 118 configured to apply and/or maintain negative pressure to the processing volume 111. A radio frequency (RF) power source 105 is coupled to the showerhead assembly 114 to facilitate formation of a plasma in a processing region 112. The processing region 112 is generally defined between the showerhead assembly 114 and the support surface 107 of the substrate support 104.

The showerhead assembly 114, backing plate 108, and the conduit 134 are generally formed from electrically conductive materials and are in electrical communication with one another. The chamber body 102 is also formed from an electrically conductive material. The chamber body 102 is generally electrically insulated from the showerhead assembly 114. In one embodiment, the showerhead assembly 114 is mounted on the chamber body 102 by a bracket 135. In one embodiment, the substrate support 104 is also electrically conductive, and the substrate support 104 is adapted to function as a shunt electrode to facilitate a ground return path for RF energy. A plurality of electrical return devices 109A, 1098 may be coupled between the substrate support 104 and the sidewall 117 and/or the bottom 119 of the chamber body 102.

Using a process gas from the processing gas source 122, the processing system 100 may be configured to deposit a variety of materials on the large area substrate 101, including but not limited to dielectric materials (e.g., SiO₂, SiOₓN_{y}, derivatives thereof or combinations thereof), semiconductive materials (e.g., Si and dopants thereof), and/or barrier materials (e.g., SiNₓ, SiOₓN_{y} or derivatives thereof). Specific examples of dielectric materials and semiconductive materials that are formed or deposited by the processing system 100 onto the large area substrate may include epitaxial silicon, polycrystalline silicon, amorphous silicon, microcrystalline silicon, silicon germanium, germanium, silicon dioxide, silicon oxynitride, silicon nitride, dopants thereof (e.g., B, P, or As), derivatives thereof or combinations thereof. The processing system 100 is also configured to receive gases such as argon, hydrogen, nitrogen, helium, or combinations thereof, for use as a purge gas or a carrier gas (e.g., Ar, H₂, N₂, He, derivatives thereof, or combinations thereof). One example of depositing silicon thin films on the large area substrate 101 using the processing system 100 may be accomplished by using silane as the precursor gas in a hydrogen carrier gas. The showerhead assembly 114 is generally disposed opposing the substrate support 104 in a substantially parallel manner to facilitate plasma generation therebetween.

A temperature control device 106 is also disposed within the substrate support 104 to control the temperature of the substrate 101 before, during, or after processing. In one aspect, the temperature control device 106 comprises a heating element to preheat the substrate 101 prior to processing. In this embodiment, the temperature control device 106 may heat the substrate support 104 to a temperature between about 200° C. and 250° C. During processing, temperatures in the processing region 112 reach or exceed 400° C. and the temperature control device 106 may comprise one or more coolant channels to cool the substrate 101. In another aspect, the temperature control device 106 may function to cool the substrate 101 after processing. Thus, the temperature control device 106 may be coolant channels, a resistive heating element, or a combination thereof. Electrical leads for the temperature control device 106 may be routed to a power source and controller (both not shown) through the hollow shaft 137.

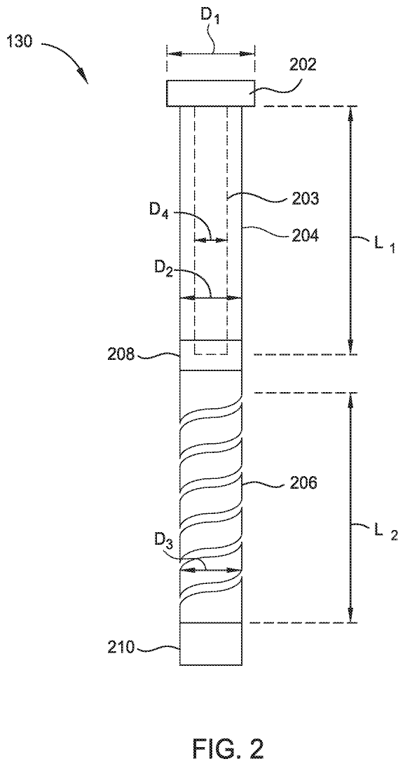

FIG. 2 is a side view of the support pin 130 according to one embodiment. As shown in FIG. 2, the support pin 130 includes a head portion 202, a first portion 203 connected to the head portion 202, and a second portion 206 connected to the first portion 203 by a connector 208. The first portion 203 is surrounded by a sleeve 204. The head portion 202 and the first portion 203 may be formed of a single piece of material. In one embodiment, the head portion 202 and the first portion 203 are fabricated from an electrically conductive material, such as a metal, for example aluminum. The head portion 202 and the first portion 203 may have an anodized surface to prevent chemical erosion. In one embodiment, the head portion 202 and the first portion 203 are fabricated from two distinct electrically conductive materials. In one embodiment, the head portion 202, the first portion 203, and the sleeve 204 are fabricated from a single piece of material, such as an electrically conductive material. In another embodiment, the head portion 202, the first portion 203, and the sleeve 204 are fabricated from a single piece of material, such as an electrically conductive material with a dielectric material surface coating such as Y₂O₃.

In one embodiment, the sleeve 204 is a straight ceramic hollow tube. The sleeve 204 is fabricated from a dielectric material, such as a ceramic material, for example Si₂O₃ or AlN. The head portion 202 has a lateral dimension D₁ that is greater than a lateral dimension D₂ of the sleeve 204. The head portion 202 prevents the support pin 130 from moving completely through the opening 125, thereby allowing the support pin 130 to be suspended when the substrate support 104 is in a raised position as shown in FIG. 1. In one embodiment, the lateral dimension D₁ is a diameter of the head portion 202.

The second portion 206 of the support pin 130 is an inductor, such as a metal coil or metal coil bar. The second portion 206 is fabricated from an electrically conductive material, such as a metal, for example aluminum. The second portion 206 of the support pin 130 helps reduce the impedance in areas of the substrate support 104 with the support pins 130. During operation, the RF power delivered to areas of the substrate support 104 without the support pins 130 is different from the RF power delivered to areas of the substrate support 104 with the support pins 130. The difference in RF power is due to a difference in the impedance caused by additional components in the RF power flow path through areas with the support pins 130. For example, an air gap is formed between the substrate 101 and the head portion 202 of the support pin 130, and an area of the head portion 202 of the support pin 130 is in contact with the substrate support 104. The second portion 206 is utilized to match the impedance of the areas of the substrate support 104 with the support pins 130 to the impedance of the areas of the substrate support 104 without the support pins 130. With the impedance of the areas of the substrate support 104 with the support pins 130 and without the support pins 130 matched, the plasma density over the areas of the substrate support 104 with the support pins 130 and without the support pins 130 is uniform, leading to improved film thickness uniformity. The uniform film thickness thus reduces or eliminates clouding or the “mura effect”.

The first portion 203 has a longitudinal dimension L₁ and a lateral dimension D₄. In one embodiment, the lateral dimension D₄ is a diameter. The lateral dimension D₄ is substantially less than the lateral dimension D₁ of the head portion 202. The second portion 206 has a longitudinal dimension L₂ and a lateral dimension D₃. In one embodiment, the lateral dimension D₃ is a diameter. The sleeve 204 has the lateral dimension D₂. In one embodiment, the lateral dimension D₂ is a diameter. In one embodiment, the longitudinal dimension L₁ of the first portion 203 is substantially greater than the longitudinal dimension L₂ of the second portion 206, such as about 30 percent to about 60 percent greater than the longitudinal dimension L₂. In one embodiment, the lateral dimension D₂ of the sleeve 204 is substantially the same as the lateral dimension D₃ of the second portion 206. In another embodiment, the lateral dimension D₂ of the sleeve 204 is substantially smaller than the lateral dimension D₃ of the second portion 206, and the second portion 206 does not move into the opening 125 of the substrate support 104 (as shown in FIG. 1) regardless of the position of the substrate support 104.

The connector 208 may be any suitable connectors, such as a threaded connector. The connector 208 is fabricated from an electrically conductive material, such as a metal, for example aluminum. An end piece 210 is connected to the second portion 206 at an end opposite the connector 208. The end piece 210 is configured to be connected to the connector 131 (FIG. 1). The end piece 210 is fabricated from an electrical conductive material, such as a metal, for example aluminum. In one embodiment, the end piece 210 is a fastener, such as a nut.

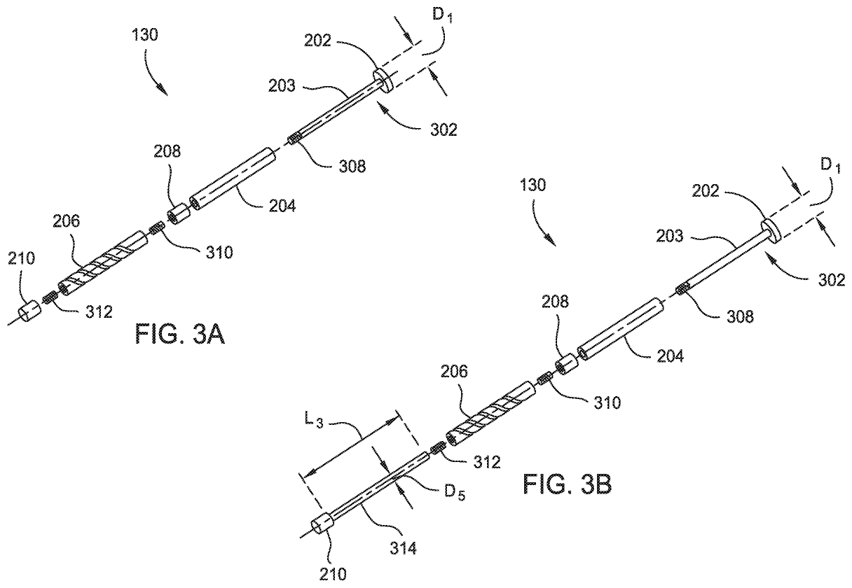

FIGS. 3A-3B are exploded views of the support pin 130 of FIG. 2 according to one embodiment. As shown in FIG. 3A, the first portion 203 is surrounded by the sleeve 204. During process, the RF current flows from the electrically conductive head portion 202 to the substrate support 104 and the first portion 203 to the ground through the second portion 206 and the connector 131 (as shown in FIG. 1). The ceramic sleeve 204 prevents RF power from flowing to the substrate support 104 from the first portion 203.

The first portion 203 is configured to be coupled to the connector 208. In one embodiment, at least a portion of the first portion 203 is threaded, and the connector 208 is a nut. In one embodiment, the second portion 206 of the support pin 130 includes a connecting portion 310 configured to be coupled to the connector 208. The connecting portion 310 and the second portion 206 may be made of a single piece of material. In one embodiment, the connecting portion 310 is threaded, and the connector 208 is a nut. In one embodiment, the connecting portion 310 of the second portion 206 is directly coupled to the first portion 203 (e.g., threaded into the sleeve 204), and the connector 208 and the connecting portion 308 are not present.

The second portion 206 may be a coil having a plurality of turns. The number of turns depends on the amount of inductance to be generated in order to match the impedance of the areas of the substrate support without the support pins 130. In one embodiment, the number of turns ranges from about 30 to 70, such as about 40 to 60. In one embodiment, the second portion 206 is hollow. A connecting member 312 connects the second portion 206 to the end piece 210. The connecting member 312 may be fabricated from an electrically conductive material, such as a metal, for example aluminum.

FIG. 3B is an exploded view of the support pin 130 according to another embodiment. As shown in FIG. 3B, the support pin 130 includes the head portion 202, the first portion 203, the sleeve 204 surrounding first portion 203, and the second portion 206 connected to the first portion 203 by the connector 208. The support pin 130 further includes a magnetic insert 314 disposed through the second portion 206. The magnetic insert 314 is fabricated from a magnetic material configured to withstand high temperatures (e.g., up to temperatures of about 300 degrees Celsius to about 450 degrees Celsius). For example, the magnetic insert 314 is fabricated from an alloy of aluminum, nickel and cobalt (Al/Ni/Co), samarium cobalt (SmCo), neodymium (Nd), or other suitable magnetic material. In one embodiment, the magnetic insert 314 is a ferrite rod. The magnetic insert 314 may be coupled to the end piece 210, as shown in FIG. 3B. In one embodiment, the second portion 206 is formed on the magnetic insert 314. The magnetic insert 314 may be utilized to change the inductance of the second portion 206 without changing the number of turns of the second portion 206. Furthermore, the magnetic insert 314 provided in each of the support pins 130 introduces a magnetic flux at positions of the support pins 130. The magnetic flux increases the plasma density at positions of the support pins 130 and therefore increases film thickness on the substrate 101 at positions of the support pins 130.

The magnetic insert 314 has a longitudinal dimension L₃ and a lateral dimension D₅. The lateral dimension D₅ of the magnetic insert 314 is substantially less than the lateral dimension D₃ of the second portion 206, because the magnetic insert 314 is configured to be inserted into the second portion 206. The longitudinal dimension L₃ of the magnetic insert 314 depends on the additional amount of inductance to be generated by the second portion 206. The longitudinal dimension L₃ of the magnetic insert 314 is less than or equal to the longitudinal dimension L₂ of the second portion 206. In one embodiment, the longitudinal dimension L₃ of the magnetic insert 314 ranges from about five percent to about 100 percent of the longitudinal dimension L₂ of the second portion 206, such as about 20 percent to about 60 percent of the longitudinal dimension L₂ of the second portion 206.

Embodiments of the support pin 130 as described herein has been tested and the addition of a second portion 206 that is an inductor as described herein significantly increases film thickness on a substrate at positions corresponding to the position of the support pin 130. The increased film thickness reduces or eliminates clouding or the “mura effect” on the substrate.

While the foregoing is directed to embodiments of the disclosure, other and further embodiments of the disclosure may be devised without departing from the basic scope thereof.

What is claimed is:

1. A substrate support pin, comprising:
a head portion having a first lateral dimension;
a first portion coupled to the head portion, the first portion having a second lateral dimension substantially less than the first dimension; and
a second portion coupled to the first portion, the second portion is a metal coil.

2. The substrate support pin of claim 1, further comprising a sleeve surrounding the first portion.

3. The substrate support pin of claim 2, wherein the sleeve comprises a ceramic material.

4. The substrate support pin of claim 3, wherein the head portion and the first portion comprise a metal.

5. The substrate support pin of claim 1, wherein the metal coil comprises aluminum.

6. The substrate support pin of claim 1, further comprising a magnetic insert disposed in the second portion.

7. The substrate support pin of claim 6, wherein the magnetic insert comprises an alloy of aluminum, nickel and cobalt (Al/Ni/Co), samarium cobalt (SmCo), or neodymium (Nd).

8. A support pedestal for a vacuum chamber, comprising;
a body having a plurality of openings formed between two major sides of the body; and
a substrate support pin disposed in each of the plurality of openings, each of the substrate support pins comprising:
a head portion having a first lateral dimension;
a first portion coupled to the head portion, the first portion having a second lateral dimension substantially less than the first dimension; and
a second portion coupled to the first portion, the second portion is a metal coil.

9. The support pedestal of claim 8, wherein the first portion has a first longitudinal dimension, the second portion has a second longitudinal dimension, and the first longitudinal dimension is substantially greater than the second longitudinal dimension.

10. The support pedestal of claim 9, further comprising a magnetic insert disposed in the second portion.

11. The support pedestal of claim 10, wherein the magnetic insert comprises an alloy of aluminum, nickel and cobalt (Al/Ni/Co), samarium cobalt (SmCo), or neodymium (Nd).

12. The support pedestal of claim 10, wherein the magnetic insert has a third longitudinal dimension less than or equal to the second longitudinal dimension of the second portion.

13. The support pedestal of claim 12, wherein the third longitudinal dimension is about five percent to about 100 percent of the second longitudinal dimension of the second portion.

14. The support pedestal of claim 8, wherein the head portion and the first portion comprise aluminum.

15. The support pedestal of claim 8, wherein the metal coil comprises aluminum.

16. An apparatus, comprising:
a chamber body defining a processing volume; and
a substrate support disposed in the processing volume, the substrate support comprising:
a body having a plurality of openings formed between two major sides of the body; and
a substrate support pin disposed in each of the plurality of openings, each of the substrate support pins comprising:
a head portion having a first lateral dimension;
a first portion coupled to the head portion, the first portion having a second lateral dimension substantially less than the first dimension; and
a second portion coupled to the first portion, the second portion being a metal coil.

17. The apparatus of claim 16, wherein the first portion has a first longitudinal dimension, the second portion has a second longitudinal dimension, and the first longitudinal dimension is substantially greater than the second longitudinal dimension.

18. The apparatus of claim 17, further comprising a magnetic insert disposed in the second portion.

19. The apparatus of claim 18, wherein the magnetic insert comprises an alloy of aluminum, nickel and cobalt (Al/Ni/Co), samarium cobalt (SmCo), or neodymium (Nd).

20. The apparatus of claim 19, wherein the magnetic insert has a third longitudinal dimension less than or equal to the second longitudinal dimension of the second portion.
